(19) United States
(12) Patent Application Publication
(10) Pub. No.: US 2014/0015580 A1
(43) Pub. Date: Jan. 16, 2014

(54) SEMICONDUCTOR DEVICE AND A POWER MANAGEMENT DEVICE USING THE SAME

(71) Applicant: SAMSUNG ELECTRONICS CO., LTD., Suwon-si (KR)

(72) Inventor: Ji-Soo CHANG, Yongin-si (KR)

(73) Assignee: SAMSUNG ELECTRONICS CO., LTD., Suwon-si (KR)

(21) Appl. No.: 13/891,248

(22) Filed: May 10, 2013

(30) Foreign Application Priority Data
Jul. 10, 2012 (KR) 10-2012-0075071

(51) Int. Cl. H03K 6/04

(52) U.S. Cl. CPC H03K 6/04
USPC 327/170

(57) ABSTRACT

A semiconductor device including, a slope signal generator configured to generate a slope signal, an error signal generator configured to generate an error signal in response to an output voltage, a pulse width modulation (PWM) signal generator configured to generate a PWM signal using a difference between the slope signal and the error signal, and a slope signal controller configured to adjust the slope signal according to a difference between the output voltage and a reference voltage.

### CROSS-REFERENCE TO RELATED APPLICATION

This application claims priority under 35 U.S.C. §119 to Korean Patent Application No. 10-2012-0075071, filed on Jul. 10, 2012 in the Korean Intellectual Property Office, the disclosure of which is incorporated by reference herein in its entirety.

### BACKGROUND

1. Technical Field

The present inventive concept relates to a semiconductor device and a power management device using the same.

2. Discussion of the Related Art

A power converter may be used to supply energy to an electronic device. The power converter may be classified as a direct current (DC)-alternating current (AC) inverter, a DC-DC converter, and an AC-DC rectifier. The DC-AC inverter changes DC to AC, the DC-DC converter converts a source of DC from one voltage level to another, and the AC-DC rectifier converts AC to DC, for example.

Of the above converters, the DC-DC converter is used to convert power supplied to a circuit system. For example, DC-DC converters are used in portable devices such as cellular phones and laptop computers, which are supplied with power from batteries primarily. The DC-DC converter may be broadly classified as a non-insulating converter and an insulating converter. Examples of the non-insulating converter include a buck converter, a boost converter and a buck-boost converter, and examples of the insulating converter include a flyback converter, a forward converter, a full-bridge converter, and a half-bridge converter.

### SUMMARY

Exemplary embodiments of the present inventive concept provide a semiconductor device which changes a duty of a pulse width modulation (PWM) signal by changing at least one of an amplitude and a central value of a slope signal according to a change in an output voltage and a change in a reference voltage.

Exemplary embodiments of the present inventive concept also provide a power management device which changes a duty of a PWM signal by changing at least one of an amplitude and a central value of a slope signal according to a change in an output voltage and a change in a reference voltage.

According to an exemplary embodiment of the present inventive concept, there is provided a semiconductor device comprising, a slope signal generator configured to generate a slope signal, an error signal generator configured to generate an error signal in response to an output voltage, a PWM signal generator configured to generate a PWM signal using a difference between the slope signal and the error signal, and a slope signal controller configured to adjust a waveform of the slope signal according to a difference between the output voltage and a reference voltage.

The slope signal controller is configured to control the slope signal to have a first amplitude in a first section and a second amplitude different from the first amplitude in a second section different from the first section according to the difference between the output voltage and the reference voltage.

The slope signal generator comprises a first comparator and a second comparator which are different from each other, wherein the first comparator is configured to determine a maximum value of the slope signal, the second comparator is configured to determine a minimum value of the slope signal, and the slope signal controller is configured to control an increase or decrease in a difference between the maximum value and the minimum value of the slope signal.

The slope signal controller is configured to control the slope signal to have a first central value in a first section and a second central value different from the first central value in a second section different from the first section according to the difference between the output voltage and the reference voltage.

The slope signal generator comprises a first comparator and a second comparator which are different from each other, wherein the first comparator is configured to determine a maximum value of the slope signal, the second comparator is configured to determine a minimum value of the slope signal, and the slope signal controller is configured to control an equal increase or decrease of the maximum and minimum values of the slope signal.

The slope signal controller is configured to control the slope signal to have a first amplitude and a first central value in a first section and a second amplitude different from the first amplitude and a second central value different from the first central value in a second section different from the first section according to the difference between the output voltage and the reference voltage.

The slope signal generator comprises a first comparator and a second comparator which are different from each other, wherein the first comparator is configured to determine a maximum value of the slope signal, the second comparator is configured to determine a minimum value of the slope signal, and the slope signal controller is configured to control individual increases or decreases in the maximum and minimum values of the slope signal.

The output voltage is a voltage that is fed back to the error signal generator according to a predetermined voltage division ratio.

According to an exemplary embodiment of the present inventive concept, there is provided a semiconductor device comprising, an error signal generator configured to generate an error signal, a slope signal generator configured to generate a slope signal which comprises a first amplitude in a first section and a second amplitude different from the first amplitude in a second section, and a PWM signal generator configured to generate a PWM signal using a difference between the slope signal and the error signal.

The semiconductor device further comprises a switch circuit configured to generate an output voltage based on the PWM signal and apply the output voltage to a load, wherein the error signal generator generates the error signal using the output voltage.

The error signal generator generates the error signal based on a result of a comparison between the output voltage and a reference voltage.

The first amplitude is a width between a minimum value and a first maximum value of the slope signal, the second amplitude is a width between the minimum value and a second maximum value of the slope signal, and the first maximum value and the second maximum value of the slope signal are different from each other.

A level of the error signal is higher than the minimum value of the slope signal.

The slope signal generator comprises a first comparator and a second comparator, wherein the first comparator is configured to determine a maximum value of the slope signal, and the second comparator is configured to determine a minimum value of the slope signal.

A difference between the maximum value and the minimum value of the slope signal in the first section is different from a difference between the maximum value and the minimum value of the slope signal in the second section.

According to an exemplary embodiment of the present inventive concept, there is provided a power management device comprising, an error amplifier configured to generate an error signal using an output voltage and a reference voltage; a first signal generator configured to generate a first signal having a variable amplitude or central oscillation point based on the output voltage and the reference voltage; and a PWM signal generator configured to generate a PWM signal using the first signal and the error signal.

The power management device further comprises a first signal controller configured to control the variability of the amplitude or central oscillation point of the first signal according to a difference between the output voltage and the reference voltage.

The output voltage is an output voltage of a switch circuit.

The first signal is a ramp signal, triangular wave signal or sawtooth wave signal.

A duty of the PWM signal is based on the error signal and first signal.

### BRIEF DESCRIPTION OF THE DRAWINGS

The above and other features of the present inventive concept will become more apparent by describing in detail exemplary embodiments thereof with reference to the attached drawings, in which:

FIG. 1 is a block diagram of a semiconductor device according to an exemplary embodiment of the present inventive concept;

FIGS. 2 and 3 are circuit diagrams of a switch circuit according to exemplary embodiments of the present inventive concept;

FIG. 4 is a diagram illustrating the operation of a pulse width modulation (PWM) signal generator according to an exemplary embodiment of the present inventive concept;

FIGS. 5 and 6 are diagrams illustrating the change in an amplitude of a slope signal according to an exemplary embodiment of the present inventive concept;

FIG. 7 is a circuit diagram of a slope signal controller and a slope signal generator according to an exemplary embodiment of the present inventive concept;

FIG. 8 is a circuit diagram of a slope signal controller and a slope signal generator according to an exemplary embodiment of the present inventive concept;

FIGS. 9 and 10 are diagrams illustrating the change in a central value of the slope signal according to an exemplary embodiment of the present inventive concept;

FIG. 11 is a circuit diagram of a slope signal controller and a slope signal generator according to an exemplary embodiment of the present inventive concept;

FIGS. 12 and 13 are diagrams illustrating the change in the amplitude and central value of the slope signal according to an exemplary embodiment of the present inventive concept; and

FIG. 14 is a circuit diagram of a slope signal controller and a slope signal generator according to an exemplary embodiment of the present inventive concept.

### DETAILED DESCRIPTION OF THE EMBODIMENTS

Exemplary embodiments of the present inventive concept will be described more fully hereinafter with reference to the accompanying drawings. This inventive concept may, however, be embodied in different forms and should not be construed as limited to the embodiments set forth herein. The same reference numbers may indicate the same components throughout the specification and drawings.

It will be understood that when an element is referred to as being “connected to” another element, it can be directly connected to the other element, or intervening elements may be present.

The use of the terms “a,” “an” and “the” are intended to include the plural forms as well, unless the context clearly indicates otherwise.

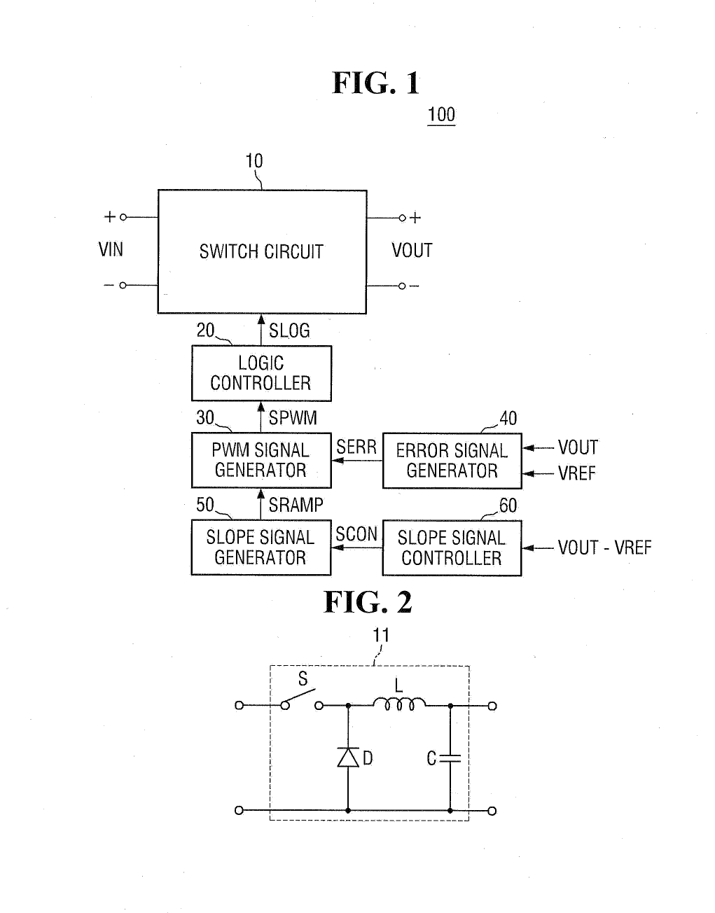

FIG. 1 is a block diagram of a semiconductor device 100 according to an exemplary embodiment of the present inventive concept.

Referring to FIG. 1, the semiconductor device 100 according to the current embodiment may be, for example, a voltage mode pulse width modulation (PWM) control direct current (DC)-DC converter. The semiconductor device 100 includes a switch circuit 10, a logic controller 20, a PWM signal generator 30, an error signal generator 40, a slope signal generator 50, and a slope signal controller 60.

The switch circuit 10 generates an output voltage VOUT according to a logic signal SLOG received from the logic controller 20 and applies the output voltage VOUT to a load. The switch circuit 10 may be configured as a step-down (or buck) circuit, a step-up (or boost) circuit, or a step down-up (or buck-boost) circuit.

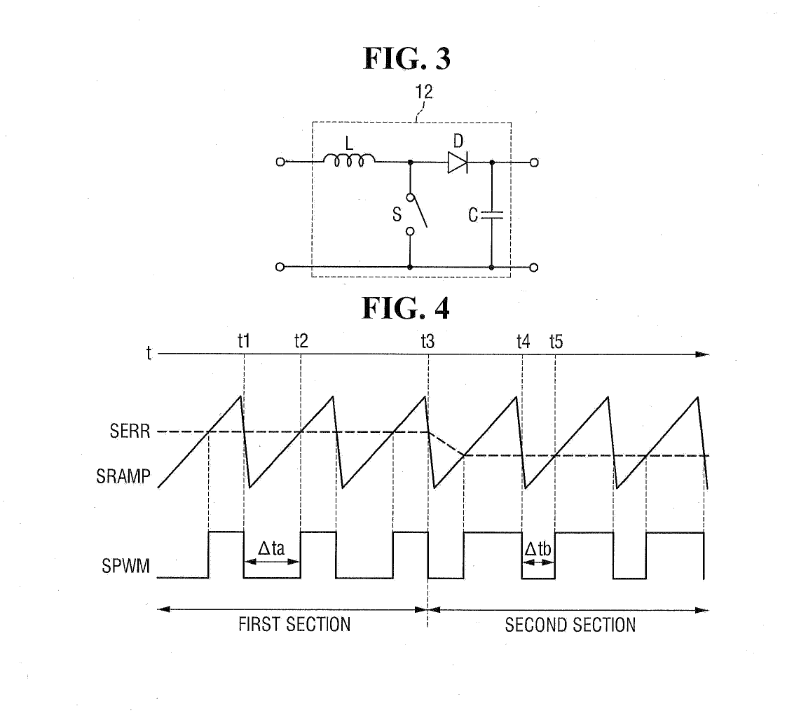

The step-down circuit steps down an input voltage by a predetermined percentage to make the input voltage appropriate for the operation of the load. The step-down circuit can be used in wireless communication devices including low-power products. The step-up circuit steps up an input voltage by a predetermined percentage to make the input voltage appropriate for the operation of the load. The step-up circuit can be used in a display driving circuit, a power management device, and the like. The step down-up circuit steps up or down an input voltage by a predetermined percentage. The configuration and operation of the step-down circuit and the step-up circuit will be described in more detail later with reference to FIGS. 2 and 3.

The logic controller 20 generates the logic signal SLOG based on a PWM signal SPWM received from the PWM signal generator 30 and controls the switch circuit 10 to operate using the logic signal SLOG. The logic controller 20 includes a gate driving buffer and may control a dead time of the PWM control DC-DC converter.

The PWM signal generator 30 generates the PWM signal SPWM using a difference between a slope signal SRAMP received from the slope signal generator 50 and an error signal SERR received from the error signal generator 40. The PWM signal generator 30 compares a level of the slope signal SRAMP received from the slope signal generator 50 with a level of the error signal SERR received from the error signal generator 40 and determines a duty of the PWM signal SPWM based on the comparison result. The operation of the PWM signal generator 30 will be described in more detail later with reference to FIG. 4.

The error signal generator 40 generates the error signal SERR using the output voltage VOUT fed back thereto. The error signal generator 40 may be, for example, an error amplifier and generate the error signal SERR based on the result of a comparison between the output voltage VOUT and a reference voltage VREF. Accordingly, the feed-back output voltage VOUT may be applied to a first (e.g., inversion) input terminal of the error amplifier, and the reference voltage VREF may be applied to a second (e.g., non-inversion) input terminal of the error amplifier. The error amplifier may compare the feed-back output voltage VOUT and the reference voltage VREF and generate the error signal SERR by amplifying an error, in other words, a difference between the output voltage VOUT and the reference voltage VREF.

The slope signal generator 50 generates the slope signal SRAMP according to a control signal SCON received from the slope signal controller 60. The slope signal generator 50 changes at least one of the amplitude and central value of the slope signal SRAMP by adjusting a waveform of the slope signal SRAMP according to the control signal SCON received from the slope signal controller 60.

The slope signal controller 60 generates the control signal SCON according to the difference between the output voltage VOUT and the reference voltage VREF and adjusts the waveform of the slope signal SRAMP using the control signal SCON. The slope signal controller 60 receives the difference between the output voltage VOUT and the reference voltage VREF and controls changes to the amplitude of the slope signal SRAMP, the central value of the slope signal SRAMP, or both the amplitude and central value of the slope signal SRAMP according to the difference between the output voltage VOUT and the reference voltage VREF.

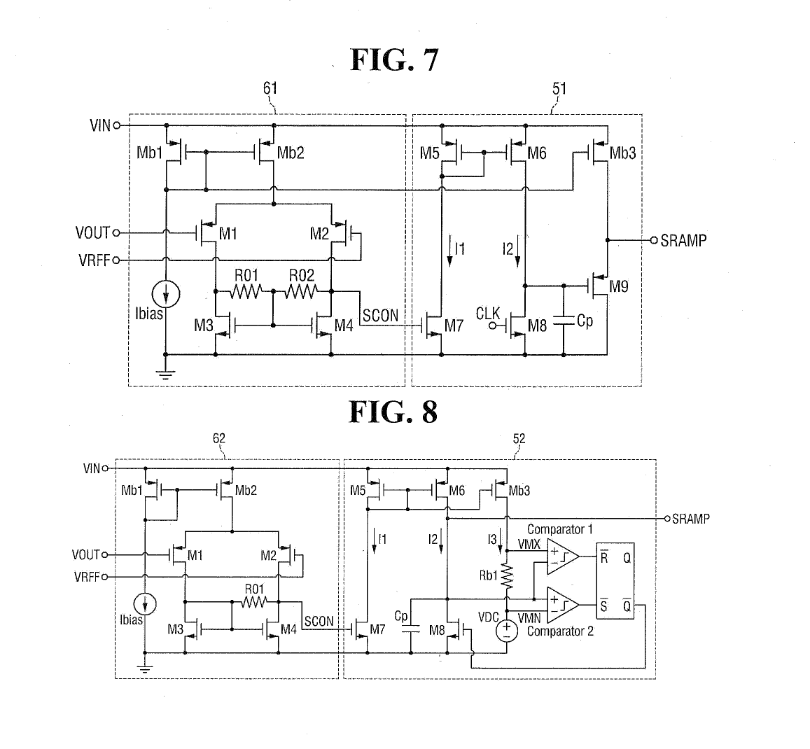

The configuration and operation of the slope signal generator 50 and the slope signal controller 60 will be described in more detail later with reference to FIGS. 7, 8, 11 and 14.

FIGS. 2 and 3 are circuit diagrams of the switch circuit 10 according to exemplary embodiments of the present inventive concept.

Referring to FIG. 2, the switch circuit 10 according to the current embodiment is configured as a step-down circuit 11. The step-down circuit 11 includes a switch S, a diode D, an inductor L, and a capacitor C.

The step-down circuit 11 shown in FIG. 2 operates as follows. As the switch S is repeatedly turned on and off in a short period of time, an input voltage having a high-frequency component is applied. Then, the high-frequency component is removed from the applied input voltage by a low pass filter which consists of the inductor L and the capacitor C. As a result, the input voltage without the high-frequency component is output. More specifically, when the switch S is turned on, the inductor L is charged with an input voltage. When the switch S is turned off, the inductor L is discharged without being supplied with the input voltage. In addition, as a current of the inductor L flows in one direction along a closed loop formed by the diode D, a stepped-down voltage is output to the capacitor C.

Referring to FIG. 3, the switch circuit 10 according to the current embodiment is configured as a step-up circuit 12. The step-up circuit 12 includes an inductor L, a switch S, a diode D, and a capacitor C.

The step-up circuit 12 shown in FIG. 3 operates as follows. As described above with reference to FIG. 2, as the switch S is repeatedly turned on and off in a short period of time, an input voltage having a high-frequency component is applied. Then, the high-frequency component is removed from the applied input voltage by a low pass filter which consists of the inductor L and the capacitor C. More specifically, when the switch S is turned on, the inductor L is charged with an input voltage. When the switch S is turned off, the inductor L is discharged at the same time the input voltage is supplied. In addition, as a current of the inductor L flows in one direction along a closed loop formed by the diode D, a stepped-up voltage is output to the capacitor C.

The switch S shown in FIGS. 2 and 3 may be a complementary metal oxide semiconductor (CMOS) device which has a P-type metal oxide semiconductor field effect transistor (MOSFET) and an N-type MOSFET connected in parallel. In this case, the PWM signal SPWM that controls the switch S may be divided and transmitted to a gate of the P-type MOSFET and a gate of the N-type MOSFET. When the P-type MOSFET is turned on by the PWM signal SPWM at a low level, an input voltage VIN is applied to the load. When the N-type MOSFET is turned on by the PWM signal SPWM at a high level, the input voltage VIN is blocked.

FIG. 4 is a diagram illustrating the operation of the PWM signal generator 30 according to an exemplary embodiment of the present inventive concept.

Referring to FIG. 4, the PWM signal generator 30 compares the slope signal SRAMP received from the slope signal generator 50 with the level of the error signal SERR received from the error signal generator 40 and determines the duty of the PWM signal SPWM based on the comparison result. The PWM signal SPWM is modulated to a high level in a section in which the slope signal SRAMP is higher than the error signal SERR and is modulated to a low level in a section in which the slope signal SRAMP is lower than the error signal SERR. As described above, when the switch S is a CMOS device, the PWM signal SPWM at a low level should be transmitted to the switch S, so that the input voltage VIN can be applied to the load. Therefore, the duty of the PWM signal SPWM is determined by a pulse width of a low section within one period. In addition, a frequency of the PWM signal SPWM is determined by a frequency of the slope signal SRAMP.

When the converter, in other words, the semiconductor device 100, operates in a normal state, the feed-back output voltage VOUT and the reference voltage VREF have the same value, and the error signal SERR generated by amplifying the difference between the output voltage VOUT and the reference voltage VREF has a constant value. Referring to FIG. 4, in a first section in which the error signal SERR is constant since the converter operates in the normal state, the PWM signal SPWM has a constant pulse width of Δta corresponding to a gap between t1 and t2.

When the converter operates in an abnormal state, the feed-back output voltage VOUT and the reference voltage VREF have different values, and the value of the error signal SERR generated by amplifying the difference between the output voltage VOUT and the reference voltage VREF changes. Referring to FIG. 4, in a second section in which the error signal SERR has a reduced value since the converter starts to operate in the abnormal state from a time t3, the PWM signal SPWM has a changed pulse width of Δtb corresponding to a gap between t4 and t5.

Here, the error signal SERR changes as the output voltage VOUT and the reference voltage VREF change, for example, as the output voltage VOUT changes according to a change in load conditions (e.g., load current) or as the reference voltage VREF is changed by force. In the event the output voltage VOUT and the reference voltage VREF change, the PWM signal SPWM is compensated according to the error signal SERR generated using the feed-back output voltage VOUT as described above, and the feed-back output voltage VOUT and the reference voltage VREF are adjusted to have the same value according to the compensated PWM signal SPWM.

When the error signal generator 40 which generates the error signal SERR performs frequency compensation using high resistance and a capacitor to ensure stability of a negative feedback, it has slow transient response time characteristics due to a high time constant and a low slew rate. The slow transient response time characteristics of the error signal generator 40 may cause the PWM control DC-DC converter to have a slow recovery time for a change in the output voltage VOUT, a change in the input voltage VIN, and a change in the reference voltage VREF.

As will be described hereinafter, the slope signal controller 60 according to the current embodiment enables the PWM control DC-DC converter to have fast transient response time characteristics by controlling the changing of at least one of the amplitude and central value of the slope signal SRAMP and the changing of the duty of the PWM signal SPWM without time delay for a change in the output voltage VOUT and a change in the reference voltage VREF. In the current embodiment, a case where the error signal SERR is a DC component is used as an example. However, the present inventive concept is not limited to this case. The same method may apply to a case where the error signal SERR is an alternating current (AC) component, for example.

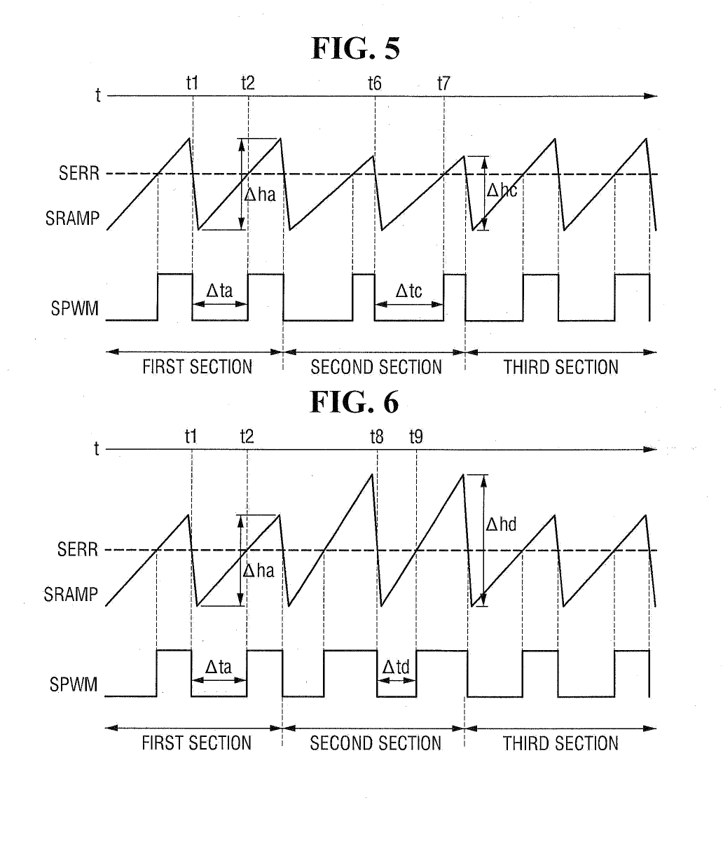

FIGS. 5 and 6 are diagrams illustrating the change in the amplitude of the slope signal SRAMP according to an exemplary embodiment of the present inventive concept. In FIGS. 5 and 6, a case where the level of the error signal SERR is higher than a minimum value of the slope signal SRAMP will be described as an example.

Referring to FIGS. 5 and 6, the slope signal SRAMP includes a first amplitude in a first section and a second amplitude different from the first amplitude in a second section different from the first section.

Referring to FIG. 5, in the first section in which the converter, in other words, the semiconductor device 100, operates in a normal state, the slope signal SRAMP includes the first amplitude corresponding to a width of Δha between a minimum value (e.g., trough) of the slope signal SRAMP and a first maximum value (e.g., crest) of the slope signal SRAMP, and the PWM signal SPWM has a constant pulse width of Δta corresponding to a gap between t1 and t2.

However, in the second section in which the feed-back output voltage VOUT is lower than the reference voltage VREF since the converter operates in an abnormal state, the slope signal SRAMP is adjusted to include the second amplitude corresponding to a width of Δhc, which is smaller than the first amplitude Δha, between the minimum value of the slope signal SRAMP and a second maximum value of the slope signal SRAMP, and the PWM signal SPWM has a pulse width of Δte which corresponds to a gap between t6 and t7 and is greater than the pulse width of Δta. Accordingly, the duty of the PWM signal SPWM increases, thereby increasing the output voltage VOUT. Thus, in a third section in which the feed-back output voltage VOUT becomes equal to the reference voltage VREF, the converter returns to the normal state.

Referring to FIG. 6, in the first section in which the converter, in other words, the semiconductor device 100, operates in the normal state, the slope signal SRAMP includes the first amplitude corresponding to a width of Δha between the minimum value of the slope signal SRAMP and the first maximum value of the slope signal SRAMP, and the PWM signal SPWM has a constant pulse width of Δta corresponding to the gap between t1 and t2.

However, in the second section in which the feed-back output voltage VOUT is higher than the reference voltage VREF, since the converter operates in the abnormal state, the slope signal SRAMP is adjusted to include the second amplitude corresponding to a width of Δhd, which is greater than the first amplitude Δha, between the minimum value of the slope signal SRAMP and the second maximum value of the slope signal SRAMP, and the PWM signal SPWM has a pulse width of Δtd which corresponds to a gap between t8 and t9 and is smaller than the pulse width of Δte. Accordingly, the duty of the PWM signal SPWM decreases, thereby decreasing the output voltage VOUT. Thus, in the third section in which the feed-back output voltage VOUT becomes equal to the reference voltage VREF, the converter returns to the normal state.

FIG. 7 is a circuit diagram of a slope signal controller 61 and a slope signal generator 51 according to an exemplary embodiment of the present inventive concept.

Referring to FIG. 7, the slope signal controller 61 according to the current embodiment includes a plurality of transistors, resistors, and a bias current source Ibias.

A first bias transistor Mb1 and a second bias transistor Mb2 form a current mirror circuit. Here, the first bias transistor Mb1 and the second bias transistor Mb2 may be, e.g., p-type MOSFETs. In this case, a gate terminal of the first bias transistor Mb1 and a gate terminal of the second bias transistor Mb2 are connected to a drain terminal of the first bias transistor Mb1. In addition, an input voltage VIN is applied to a source terminal of the first bias transistor Mb1 and a source terminal of the second bias transistor Mb2.

The bias current source Ibias supplies a bias current for driving the slope signal controller 61. A first terminal of the bias current source Ibias is connected to the drain terminal of the first bias transistor Mb1, and a second terminal of the bias current source Ibias is connected to ground.

A first transistor M1 and a second transistor M2 form a differential pair circuit. Here, the first transistor M1 and the second transistor M2 may be, e.g., p-type MOSFETs. In this case, a source terminal of the first transistor M1 and a source terminal of the second transistor M2 are connected to a drain terminal of the second bias transistor Mb2. In addition, the output voltage VOUT is applied to a gate terminal of the first transistor M1, and the reference voltage VREF is applied to a gate terminal of the second transistor M2.

A third transistor M3 and a fourth transistor M4 are designed for inversion output. The third transistor M3 and the fourth transistor M4 may be, e.g., n-type MOSFETs. A drain terminal of the third transistor M3 is connected to a drain terminal of the first transistor M1 and a first terminal of a first output resistor RO1, and a source terminal of the third transistor M3 is connected to the ground. A drain terminal of the fourth transistor M4 is connected to a drain terminal of the second transistor M2 and a first terminal of a second output resistor RO2, and a source terminal of the fourth transistor M4 is connected to the ground. A gate terminal of the third transistor M3 and a gate terminal of the fourth transistor M4 are connected to each other, and a second terminal of the first output resistor RO1 and a second terminal of the second output resistor RO2 are connected to the gate terminal of the third transistor M3 and the gate terminal of the fourth transistor M4.

The first output resistor RO1 can be removed. In this case, the gate terminal of the third transistor M3 and the second terminal of the second output resistor RO2 can be directly connected to the drain terminal of the third transistor M3.

The slope signal generator 51 according to the current embodiment includes a plurality of transistors and a capacitor Cp.

A fifth transistor M5 and a sixth transistor M6 form a current mirror circuit. Here, the fifth transistor M5 and the sixth transistor M6 may be, e.g., p-type MOSFETs. In this case, a gate terminal of the fifth transistor M5 and a gate terminal of the sixth transistor M6 are connected to a drain terminal of the fifth transistor M5. In addition, the input voltage VIN is applied to a source terminal of the fifth transistor M5 and a source terminal of the sixth transistor M6.

A seventh transistor M7 is designed to receive the control signal SCON of the slope signal controller 61. The seventh transistor M7 may be, e.g., an n-type MOSFET. In this case, a gate terminal of the seventh transistor M7 is connected to the first terminal of the second output resistor RO2. In addition, a drain terminal of the seventh transistor M7 is connected to the drain terminal of the fifth transistor M5, and a source terminal of the seventh transistor M7 is connected to the ground.

An eighth transistor M8 is designed to receive a clock signal CLK. The eighth transistor M8 may be, e.g., an n-type MOSFET. A drain terminal of the eighth transistor M8 is connected to a drain terminal of the sixth transistor M6, the clock signal CLK is transmitted to a gate terminal of the eighth transistor M8, and a source terminal of the eighth transistor M8 is connected to the ground.

A third bias transistor Mb3 forms a current mirror circuit together with the first bias transistor Mb1 and the second bias transistor Mb2. Here, the third bias transistor Mb3 may be, e.g., a p-type MOSFET. In this case, a gate terminal of the third bias transistor Mb3 is connected to the drain terminal of the first bias transistor Mb1. In addition, the input voltage VIN is applied to a source terminal of the third bias transistor Mb3.

The capacitor Cp is designed to generate the slope signal SRAMP using an inter-terminal voltage thereof. A first terminal of the capacitor Cp is connected to the drain terminal of the eighth transistor M8, and a second terminal of the capacitor Cp is connected to the ground.

A ninth transistor M9 is designed to shift the inter-terminal voltage of the capacitor Cp. The ninth transistor M9 may be, e.g., a p-type MOSFET. In this case, a gate terminal of the ninth transistor M9 is connected to the first terminal of the capacitor Cp, and a drain terminal of the ninth transistor M9 is connected to the ground. In addition, a source terminal of the ninth transistor M9 is connected to a drain terminal of the third bias transistor Mb3 and used as a terminal that outputs the slope signal SRAMP.

When the slope signal controller 61 and the slope signal generator 51 are configured as shown in FIG. 7, the amplitude of the slope signal SRAMP is changed as follows.

Since the first bias transistor Mb1, the second bias transistor Mb2, and the third bias transistor Mb3 form a current mirror circuit, the same bias current supplied by the bias current source Ibias flows through the drain terminal of the first bias transistor Mb1, the drain terminal of the second bias transistor Mb2, and the drain terminal of the third bias transistor Mb3.

In addition, since the first transistor M1 and the second transistor M2 form a differential pair circuit that receives the output voltage VOUT and the reference voltage VREF, a control voltage corresponding to the difference between the output voltage VOUT and the reference voltage VREF is output as the control signal SCON.

More specifically, when the difference between the output voltage VOUT and the reference voltage VREF is greater than zero (for example, when the output voltage VOUT increases while the reference voltage VREF is fixed or when the reference voltage VREF decreases while the output voltage VOUT is fixed), a current flowing through a drain terminal of the first transistor M1 is reduced. Since the first transistor M1 and the second transistor M2 form a differential pair circuit, the sum of the current flowing through the drain terminal of the first transistor M1 and a current flowing through the drain terminal of the second transistor M2 should be constant. Thus, the current flowing through the drain terminal of the second transistor M2 increases. The increased current flowing through the drain terminal of the second transistor M2 increases a control voltage at the first terminal of the second output resistor RO2.

Conversely, when the difference between the output voltage VOUT and the reference voltage VREF is smaller than zero (for example, when the output voltage VOUT decreases while the reference voltage VREF is fixed or when the reference voltage VREF increases while the output voltage VOUT is fixed), the current flowing through the drain terminal of the first transistor M1 increases. Since the first transistor M1 and the second transistor M2 form a differential pair circuit, the sum of the current flowing through the drain terminal of the first transistor M1 and the current flowing through the drain terminal of the second transistor M2 should be constant. Thus, the current flowing through the drain terminal of the second transistor M2 decreases. The decreased current flowing through the drain terminal of the second transistor M2 decreases the control voltage at the first terminal of the second output resistor RO2.

As the control voltage increases or decreases, a current flowing into the capacitor Cp increases or decreases. In addition, the amplitude of the slope signal SRAMP is changed by increasing or decreasing a voltage that charges the capacitor Cp.

More specifically, when the control voltage increases since the difference between the output voltage VOUT and the reference voltage VREF is greater than zero, a current I1 flowing through the drain terminal of the fifth transistor M5 increases. Since the fifth transistor M5 and the sixth transistor M6 form a current mirror circuit, when the current I1 flowing through the drain terminal of the fifth transistor M5 increases, a current I2 flowing through the drain terminal of the sixth transistor M6 also increases. Accordingly, the current flowing into the capacitor Cp increases, thereby increasing the voltage that charges the capacitor Cp.

Conversely, when the control voltage decreases since the difference between the output voltage VOUT and the reference voltage VREF is smaller than zero, the current I1 flowing through the drain terminal of the fifth transistor M5 decreases. Since the fifth transistor M5 and the sixth transistor M6 form a current mirror circuit, when the current I1 flowing through the drain terminal of the fifth transistor M5 decreases, the current I2 flowing through the drain terminal of the sixth transistor M6 also decreases. Accordingly, the current flowing into the capacitor Cp decreases, thereby reducing the voltage that charges the capacitor Cp.

Since the clock signal CLK is transmitted to the gate terminal of the eighth transistor M8, the current I2 flowing through the drain terminal of the sixth transistor M6 flows into the capacitor Cp in a low section of the clock signal CLK, thereby charging the inter-terminal voltage of the capacitor Cp. Here, the slope signal SRAMP increases linearly, and the amplitude of the slope signal SRAMP corresponds to the inter-terminal voltage of the capacitor Cp. In a high section of the clock signal CLK, the eighth transistor M8 short-circuits as it is turned on. Therefore, the current I2 flowing through the drain terminal of the sixth transistor M6 flows into the eighth transistor M8, thereby discharging the inter-terminal voltage of the capacitor Cp. Here, the slope signal SRAMP decreases linearly to its central value (e.g., a minimum value in the case of a ramp signal).

Since the gate terminal of the ninth transistor M9 is connected to the first terminal of the capacitor Cp, the inter-terminal voltage of the capacitor Cp is amplified by a predetermined percentage and then output as the slope signal SRAMP. Accordingly, the central value of the slope signal SRAMP may be a value other than zero.

FIG. 8 is a circuit diagram of a slope signal controller 62 and a slope signal generator 52 according to an exemplary embodiment of the present inventive concept. A detailed description of elements similar to those shown in FIG. 7 will be omitted.

Referring to FIG. 8, the slope signal controller 62 according to the current embodiment includes a plurality of transistors, a resistor, and a bias current source Ibias.

A first transistor M1 and a second transistor M2 form a differential pair circuit. Here, the first transistor M1 and the second transistor M2 may be, e.g., p-type MOSFETs. In this case, a source terminal of the first transistor M1 and a source terminal of the second transistor M2 are connected to a drain terminal of a second bias transistor Mb2. In addition, the output voltage VOUT is applied to a gate terminal of the first transistor M1, and the reference voltage VREF is applied to a gate terminal of the second transistor M2.

A third transistor M3 and a fourth transistor M4 are designed for inversion output. The third transistor M3 and the fourth transistor M4 may be, e.g., n-type MOSFETs. A drain terminal of the third transistor M3 is connected to a drain terminal of the first transistor M1, and a source terminal of the third transistor M3 is connected to the ground. A drain terminal of the fourth transistor M4 is connected to a drain terminal of the second transistor M2 and a first terminal of a first output resistor RO1, and a source terminal of the fourth transistor M4 is connected to the ground. A gate terminal of the third transistor M3 and a gate terminal of the fourth transistor M4 are connected to each other, and a second terminal of the first output resistor RO1 and a drain terminal of the first transistor M1 are connected to the gate terminal of the third transistor M3 and the gate terminal of the fourth transistor M4.

Here, at least one output resistor can also be connected between the second terminal of the first output resistor RO1 and the drain terminal of the first transistor M1.

The slope signal generator 52 according to the current embodiment includes a plurality of transistors, a capacitor Cp, resistors, a voltage source, comparators, and a set-reset (SR) latch.

A fifth transistor M5 and a sixth transistor M6 form a current mirror circuit. Here, the fifth transistor M5 and the sixth transistor M6 may be, e.g., p-type MOSFETs. In this case, a gate terminal of the fifth transistor M5 and a gate terminal of the sixth transistor M6 are connected to a drain terminal of the fifth transistor M5. In addition, the input voltage VIN is applied to a source terminal of the fifth transistor M5 and a source terminal of the sixth transistor M6.

A seventh transistor M7 is designed to receive the control signal SCON of the slope signal controller 62. The seventh transistor M7 may be, e.g., an n-type MOSFET. In this case, a gate terminal of the seventh transistor M7 is connected to the first terminal of the first output resistor RO1. In addition, a drain terminal of the seventh transistor M7 is connected to the drain terminal of the fifth transistor M5, and a source terminal of the seventh transistor M7 is connected to the ground.

An eighth transistor M8 is designed to receive an output of the SR latch. The eighth transistor M8 may be, e.g., an n-type MOSFET. A drain terminal of the eighth transistor M8 is connected to a drain terminal of the sixth transistor M6, an output Q′ of the SR latch is applied to a gate terminal of the eighth transistor M8, and a source terminal of the eighth transistor M8 is connected to the ground.

A third bias transistor Mb3 forms a current mirror circuit together with the fifth transistor M5. Here, the third bias transistor Mb3 may be, e.g., a p-type MOSFET. In this case, a gate terminal of the third bias transistor Mb3 is connected to the drain terminal of the fifth transistor M5. In addition, the input voltage VIN is applied to a source terminal of the third bias transistor Mb3.

The capacitor Cp is designed to generate a slope signal SRAMP using an inter-terminal voltage thereof. A first terminal of the capacitor Cp is connected to the drain terminal of the eighth transistor M8 and used as a terminal that outputs the slope signal SRAMP. A second terminal of the capacitor Cp is connected to the ground.

A first comparator Comparator 1, a second comparator Comparator 2, and the SR latch control an output of the slope signal SRAMP to oscillate in a predetermined section.

A first (e.g., non-inversion) input terminal of the first comparator Comparator 1 is connected to a drain terminal of the third bias transistor Mb3, and a second (e.g., inversion) input terminal of the first comparator Comparator 1 is connected to the first terminal of the capacitor Cp. A first (e.g., non-inversion) input terminal of the second comparator Comparator 2 is connected to the first terminal of the capacitor Cp, and a second (e.g., inversion) input terminal of the second comparator Comparator 2 is connected to a first terminal of the voltage source. A first resistor Rb1 is connected between the first input terminal of the first comparator Comparator 1 and the second input terminal of the second comparator Comparator 2, and a second terminal of the voltage source is connected to the ground.

The SR latch may be, e.g., an SR complement latch. An output terminal of the first comparator Comparator 1 is connected to an input R′ of the SR latch, and an output terminal of the second comparator Comparator 2 is connected to an input S′ of the SR latch.

When the slope signal controller 62 and the slope signal generator 52 are configured as shown in FIG. 8, the amplitude of the slope signal SRAMP is changed as follows.

Since the first transistor M1 and the second transistor M2 form a differential pair circuit that receives the output voltage VOUT and the reference voltage VREF, a control voltage corresponding to the difference between the output voltage VOUT and the reference voltage VREF is output as the control signal SCON.

More specifically, when the difference between the output voltage VOUT and the reference voltage VREF is greater than zero (for example, when the output voltage VOUT increases while the reference voltage VREF is fixed or when the reference voltage VREF decreases while the output voltage VOUT is fixed), a current flowing through the drain terminal of the first transistor M1 is reduced. Since the first transistor M1 and the second transistor M2 form a differential pair circuit, the sum of the current flowing through the drain terminal of the first transistor M1 and a current flowing through the drain terminal of the second transistor M2 should be constant. Thus, the current flowing through the drain terminal of the second transistor M2 increases. The increased current flowing through the drain terminal of the second transistor M2 increases a control voltage at the first terminal of the first output resistor RO1.

Conversely, when the difference between the output voltage VOUT and the reference voltage VREF is smaller than zero (for example, when the output voltage VOUT decreases while the reference voltage VREF is fixed or when the reference voltage VREF increases while the output voltage VOUT is fixed), the current flowing through the drain terminal of the first transistor M1 increases. Since the first transistor M1 and the second transistor M2 form the differential pair circuit, the sum of the current flowing through the drain terminal of the first transistor M1 and the current flowing through the drain terminal of the second transistor M2 should be constant. Thus, the current flowing through the drain terminal of the second transistor M2 decreases. The decreased current flowing through the drain terminal of the second transistor M2 decreases the control voltage at the first terminal of the first output resistor RO1.

As the control voltage increases or decreases, a current flowing into the capacitor Cp increases or decreases. In addition, the amplitude of the slope signal SRAMP is changed by increasing or decreasing a difference between maximum and minimum values of the slope signal SRAMP as well as a voltage that charges the capacitor Cp.

More specifically, when the control voltage increases since the difference between the output voltage VOUT and the reference voltage VREF is greater than zero, a current I1 flowing through the drain terminal of the fifth transistor M5 increases. Since the fifth transistor M5 and the sixth transistor M6 form a current mirror circuit, when the current I1 flowing through the drain terminal of the fifth transistor M5 increases, a current I2 flowing through the drain terminal of the sixth transistor M6 also increases. Accordingly, the current flowing into the capacitor Cp increases, thereby increasing the voltage that charges the capacitor Cp.

Conversely, when the control voltage decreases since the difference between the output voltage VOUT and the reference voltage VREF is smaller than zero, the current I1 flowing through the drain terminal of the fifth transistor M5 decreases. Since the fifth transistor M5 and the sixth transistor M6 form the current mirror circuit, when the current I1 flowing through the drain terminal of the fifth transistor M5 decreases, the current I2 flowing through the drain terminal of the sixth transistor M6 also decreases. Accordingly, the current flowing into the capacitor Cp decreases, thereby reducing the voltage that charges the capacitor Cp.

The first comparator Comparator 1 determines the maximum value of the slope signal SRAMP, and the second comparator Comparator 2 determines the minimum value of the slope signal SRAMP. Accordingly, a voltage applied to the first input terminal of the first comparator Comparator 1 is used as a reference maximum value VMX of the slope signal SRAMP, and a voltage applied to the second input terminal of the second comparator Comparator 2 is used as a reference minimum value VMN of the slope signal SRAMP. When the level of the slope signal SRAMP is higher than the reference maximum value VMX, the input R′ of the SR latch is low (e.g., zero), and the input S′ of the SR latch is high (e.g., one). Accordingly, the output Q′ of the SR latch is high, and thus the eighth transistor M8 is turned on. As the eighth transistor M8 is turned on, it short-circuits, causing the capacitor Cp to be discharged. On the other hand, when the level of the slope signal SRAMP is lower than the reference minimum value VMN, the input R′ of the SR latch is high, and the input S′ of the SR latch is low. Accordingly, the output Q′ of the SR latch is low, and thus the eighth transistor M8 is turned off. As the eighth transistor M8 is turned off, it is opened, allowing the capacitor Cp to be charged. When the level of the slope signal SRAMP is lower than the reference maximum value VMX and higher than the reference minimum value VMN, the input R′ of the SR latch is high, and the input S′ of the SR latch is high. Accordingly, the output Q′ of the SR latch is Q′, and thus the eighth transistor M8 maintains a previous state.

The voltage source may apply, e.g., a DC constant voltage VDC to the second input terminal of the second comparator Comparator 2, and the DC constant voltage VDC applied to the second input terminal of the second comparator Comparator 2 is used as the reference minimum value VMN of the slope signal SRAMP. An inter-terminal voltage of the first resistor Rb1 connected between the first input terminal of the first comparator Comparator 1 and the second input terminal of the second comparator Comparator 2 corresponds to a difference between the maximum and minimum values of the slope signal SRAMP and increases or decreases as a current I3 flowing through the drain terminal of the third bias transistor Mb3 increases or decreases. In addition, since the third bias transistor Mb3 forms a current mirror circuit together with the fifth transistor M5, the current I3 flowing through the drain terminal of the third bias transistor Mb3 increases or decreases as a current flowing through the drain terminal of the fifth transistor M5 increases or decreases.

Therefore, when the current I1 flowing through the drain terminal of the fifth transistor M5 increases, the current I2 flowing through the drain terminal of the sixth transistor M6 increases, thereby increasing the voltage that charges the capacitor Cp. In addition, the current I3 flowing through the drain terminal of the third bias transistor Mb3 increases, and thus the inter-terminal voltage of the first resistor Rb1 increases. In this case, the inter-terminal voltage of the capacitor Cp is charged to the increased reference maximum value VMX (e.g., a value obtained by adding the inter-terminal voltage of the first resistor Rb1 to the DC constant voltage VDC) of the slope signal SRAMP. Accordingly, since the difference between the maximum and minimum values of the slope signal SRAMP increases while the minimum value of the slope signal SRAMP is fixed, the amplitude of the slope signal SRAMP increases.

Conversely, when the current I1 flowing through the drain terminal of the fifth transistor M5 decreases, the current I2 flowing through the drain terminal of the sixth transistor M6 decreases, thereby decreasing the voltage that charges the capacitor Cp. In addition, the current I3 flowing through the drain terminal of the third bias transistor Mb3 decreases, and thus the inter-terminal voltage of the first resistor Rb1 decreases. In this case, the inter-terminal voltage of the capacitor Cp is charged to the decreased reference maximum value VMX of the slope signal SRAMP. Accordingly, since the difference between the maximum and minimum values of the slope signal SRAMP decreases while the minimum value of the slope signal SRAMP is fixed, the amplitude of the slope signal SRAMP decreases.

If the reference maximum value VMX of the slope signal SRAMP does not increase or decrease, the amplitude of the slope signal SRAMP does not change even when the inter-terminal voltage of the capacitor Cp increases or decreases because the state of the eighth transistor M8 varies according to the outputs of the first and second comparators Comparator 1 and Comparator 2.

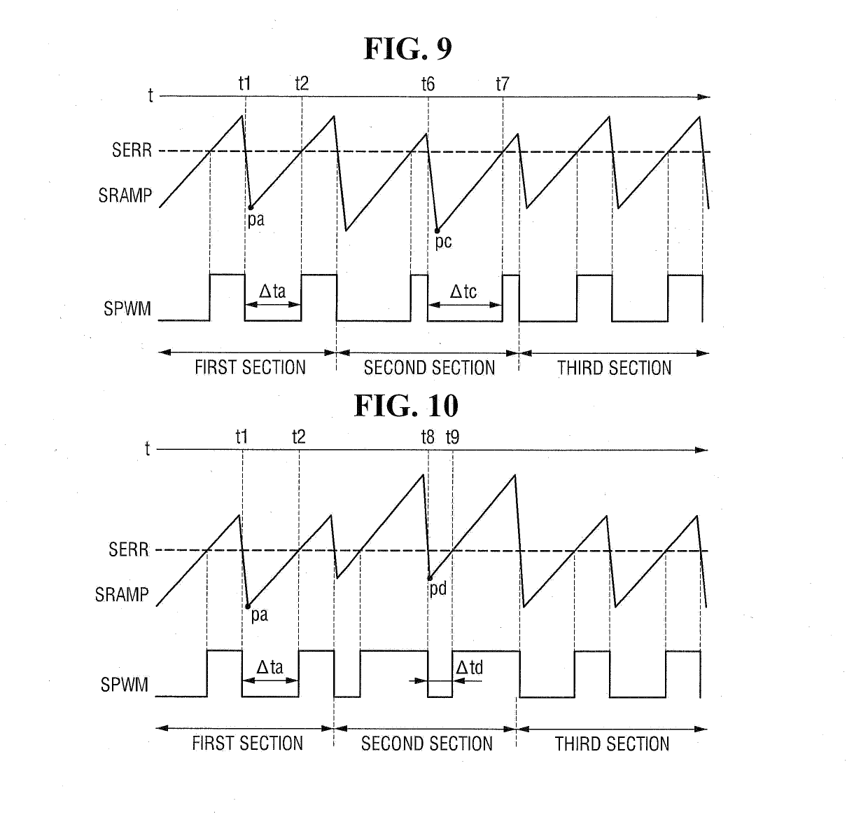

FIGS. 9 and 10 are diagrams illustrating the change in the central value of the slope signal SRAMP according to an exemplary embodiment of the present inventive concept. In FIGS. 9 and 10, a case where the level of the error signal SERR is higher than the minimum value of the slope signal SRAMP will be described as an example.

Referring to FIGS. 9 and 10, the slope signal SRAMP includes a first central value in a first section and a second central value different from the first central value in a second section different from the first section. Here, a central value indicates the center of oscillation of a waveform of the slope signal SRAMP. In the current embodiment of the present inventive concept, a case where the central value is the minimum value of the slope signal SRAMP will be described as an example.

Referring to FIG. 9, in the first section in which the converter, in other words, the semiconductor device 100, operates in a normal state, the slope signal SRAMP includes the first central value corresponding to pa as a first minimum value, and the PWM signal SPWM has a constant pulse width of Δta corresponding to a gap between t1 and t2.

However, in the second section in which the feed-back output voltage VOUT is lower than the reference voltage VREF since the converter operates in an abnormal state, the maximum and minimum values of the slope signal SRAMP decrease equally. Thus, the slope signal SRAMP is adjusted to include the second central value corresponding to pc, which is lower than the first central value pa, as a second minimum value, and the PWM signal SPWM has a pulse width of Δte which corresponds to a gap between t6 and t7 and is greater than the pulse width of Δta. Accordingly, the duty of the PWM signal SPWM increases, thereby increasing the output voltage VOUT. In a third section in which the feed-back output voltage VOUT becomes equal to the reference voltage VREF, the converter returns to the normal state.

Referring to FIG. 10, in the first section in which the converter, in other words, the semiconductor device 100, operates in the normal state, the slope signal SRAMP includes the first central value corresponding to pa as the first minimum value, and the PWM signal SPWM has a constant pulse width of Δta corresponding to the gap between t1 and t2.

However, in the second section in which the feed-back output voltage VOUT is higher than the reference voltage VREF since the converter operates in the abnormal state, the maximum and minimum values of the slope signal SRAMP increase simultaneously. Thus, the slope signal SRAMP is adjusted to include the second central value corresponding to pd, which is higher than the first central value pa, as the second minimum value, and the PWM signal SPWM has a pulse width of Δtd which corresponds to a gap between t8 and t9 and is smaller than the pulse width of Δte. Accordingly, the duty of the PWM signal SPWM decreases, thereby decreasing the output voltage VOUT. In the third section in which the feed-back output voltage VOUT becomes equal to the reference voltage VREF, the converter returns to the normal state.

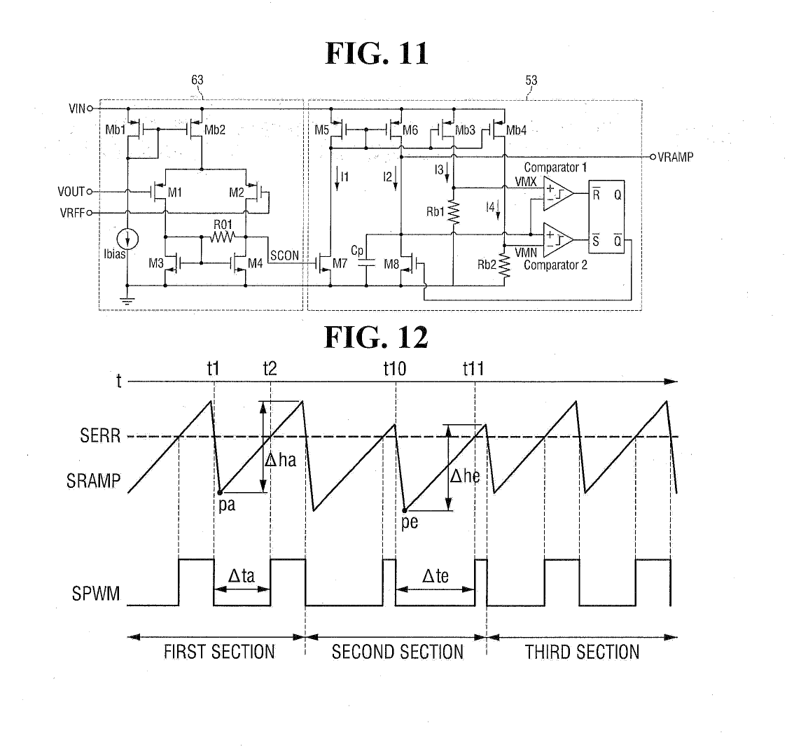

FIG. 11 is a circuit diagram of a slope signal controller 63 and a slope signal generator 53 according to an exemplary embodiment of the present inventive concept. A detailed description of elements similar to those shown in FIG. 8 will be omitted.

Referring to FIG. 11, the slope signal controller 63 according to the current embodiment includes a plurality of transistors, a resistor, and a bias current source Ibias. The slope signal generator 53 according to the current embodiment includes a plurality of transistors, a capacitor Cp, resistors, comparators, and an SR latch.

A third bias transistor Mb3 forms a current mirror circuit together with a fifth transistor M5. Here, the third bias transistor Mb3 may be, e.g., a p-type MOSFET. In this case, a gate terminal of the third bias transistor Mb3 is connected to a drain terminal of the fifth transistor M5. In addition, the input voltage VIN is applied to a source terminal of the third bias transistor Mb3.

A fourth bias transistor Mb4 also forms a current mirror circuit together with the fifth transistor M5. Here, the fourth bias transistor Mb4 may be, e.g., a p-type MOSFET. In this case, a gate terminal of the fourth bias transistor Mb4 is connected to the drain terminal of the fifth transistor M5. In addition, the input voltage VIN is applied to a source terminal of the fourth bias transistor Mb4.

A first (e.g., non-inversion) input terminal of a first comparator Comparator 1 is connected to a drain terminal of the third bias transistor Mb3, and a second (e.g., inversion) input terminal of the first comparator Comparator 1 is connected to a first terminal of the capacitor Cp. A first (e.g., non-inversion) input terminal of a second comparator Comparator 2 is connected to the first terminal of the capacitor Cp, and a second (e.g., inversion) input terminal of the second comparator Comparator 2 is connected to a drain terminal of the fourth bias transistor Mb4. A first terminal of a first resistor Rb1 is connected to the first input terminal of the first comparator Comparator 1 and the drain terminal of the third bias transistor Mb3, and a first terminal of a second resistor Rb2 is connected to the second input terminal of the second comparator Comparator 2 and the drain terminal of the fourth bias transistor Mb4. A second terminal of the first resistor Rb1 and a second terminal of the second resistor Rb2 are connected to the ground.

When the slope signal controller 63 and the slope signal generator 53 are configured as shown in FIG. 11, the central value of the slope signal SRAMP is changed as follows.

As described above for FIG. 8, as the control voltage increases or decreases, the current flowing into the capacitor Cp increases or decreases. The central value of the slope signal SRAMP can be changed by equally increasing or decreasing the maximum and minimum values of the slope signal SRAMP as well as a voltage that charges the capacitor Cp.

The first comparator Comparator 1 determines the maximum value of the slope signal SRAMP, and the second comparator Comparator 2 determines the minimum value of the slope signal SRAMP. Accordingly, an inter-terminal voltage of the first resistor Rb1 connected to the first input terminal of the first comparator Comparator 1 is used as the reference maximum value VMX of the slope signal SRAMP, and an inter-terminal voltage of the second resistor Rb2 connected to the second input terminal of the second comparator Comparator 2 is used as the reference minimum value VMN of the slope signal SRAMP. Accordingly, when a current I3 flowing through the drain terminal of the third bias transistor Mb3 increases or decreases, the reference maximum value VMX of the slope signal SRAMP increases or decreases. In addition, when a current flowing through the drain terminal of the fifth transistor M5 increases or decreases, the reference minimum value VMN of the slope signal SRAMP increases or decreases.

Therefore, when a current I1 flowing through the drain terminal of the fifth transistor M5 increases, a current I2 flowing through a drain terminal of a sixth transistor M6 increases, thereby increasing the voltage that charges the capacitor Cp. In addition, the current I3 flowing through the drain terminal of the third bias transistor Mb3 and a current I4 flowing through the drain terminal of the fourth bias transistor Mb4 increase, and thus the inter-terminal voltage of the first resistor Rb1 and the inter-terminal voltage of the second resistor Rb2 increase. In this case, the inter-terminal voltage of the capacitor Cp is charged to the increased reference maximum value VMX (e.g., the inter-terminal voltage of the first resistor Rb1) of the slope signal SRAMP and then discharged to the increased reference minimum value VMN (e.g., the inter-terminal voltage of the second resistor Rb2) of the slope signal SRAMP. Here, since the inter-terminal voltage of the second resistor Rb2) of the slope signal SRAMP. Here, since the difference between the maximum and minimum values of the slope signal SRAMP which corresponds to the amplitude of the slope signal SRAMP, in other words, a difference between the inter-terminal voltage of the first resistor Rb1 and the inter-terminal voltage of the second resistor Rb2 is maintained constant, only the central value of the slope signal SRAMP increases.

Conversely, when the current I1 flowing through the drain terminal of the fifth transistor M5 decreases, the current I2 flowing through the drain terminal of the sixth transistor M6 decreases, thereby decreasing the voltage that charges the capacitor Cp. In addition, the current I3 flowing through the drain terminal of the third bias transistor Mb3 and the current I4 flowing through the drain terminal of the fourth bias transistor Mb4 decrease, and thus the inter-terminal voltage of the first resistor Rb1 and the inter-terminal voltage of the second resistor Rb2 decrease. In this case, the inter-terminal voltage of the capacitor Cp is charged to the decreased reference maximum value VMX of the slope signal SRAMP and then discharged to the decreased reference minimum value VMN of the slope signal SRAMP. Here, since the difference between the maximum and minimum values of the slope signal SRAMP which corresponds to the amplitude of the slope signal SRAMP is maintained constant, in other words, the difference between the inter-terminal voltage of the first resistor Rb1 and the inter-terminal voltage of the second resistor Rb2 is maintained constant, only the central value of the slope signal SRAMP decreases.

If the reference maximum value VMX and the reference minimum value VMN of the slope signal SRAMP do not increase or decrease equally while maintaining a constant difference between them, the central value of the slope signal SRAMP does not change even when the inter-terminal voltage of the capacitor Cp increases or decreases because the state of an eighth transistor M8 varies according to the outputs of the first and second comparators Comparator 1 and Comparator 2.

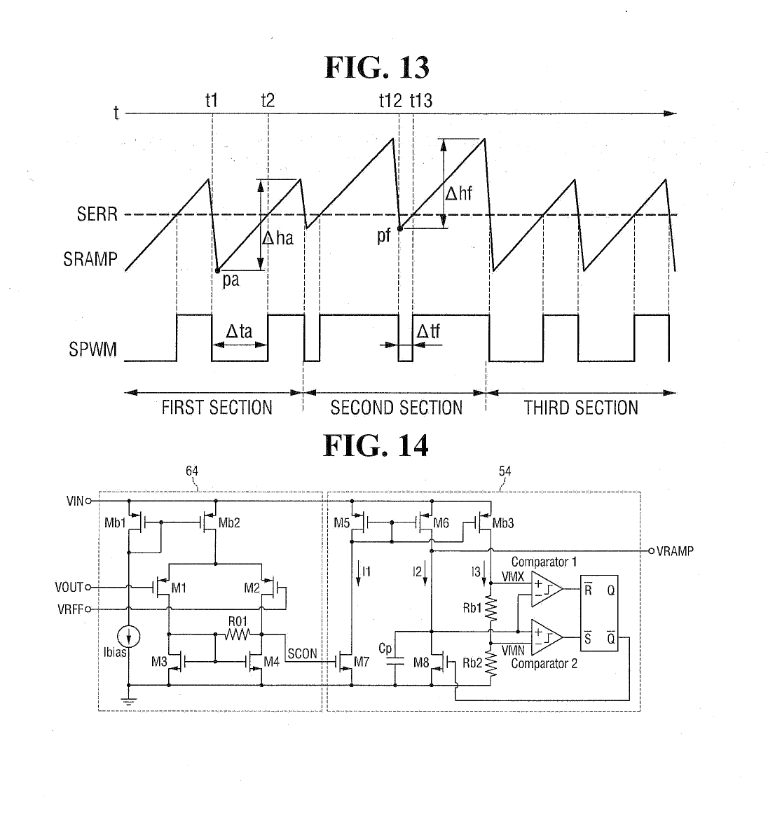

FIGS. 12 and 13 are diagrams illustrating the change in the amplitude and central value of the slope signal SRAMP according to an exemplary embodiment of the present inventive concept. In FIGS. 12 and 13, a case where the level of the error signal SERR is higher than the minimum value of the slope signal SRAMP will be described as an example.

Referring to FIGS. 12 and 13, the slope signal SRAMP includes a first amplitude and a first central value in a first section and a second amplitude different from the first amplitude and a second central value different from the first central value in a second section different from the first section.

Referring to FIG. 12, in the first section in which the converter, in other words, the semiconductor device 100, operates in a normal state, the slope signal SRAMP includes the first amplitude corresponding to a width of Δha between the minimum value of the slope signal SRAMP and a first maximum value of the slope signal SRAMP. In addition, the slope signal SRAMP includes the first central value corresponding to pa as a first minimum value, and the PWM signal SPWM has a constant pulse width of Δta corresponding to a gap between t1 and t2.

However, in the second section in which the feed-back output voltage VOUT is lower than the reference voltage VREF since the converter operates in an abnormal state, the slope signal SRAMP includes the second amplitude corresponding to a width of Δhe, which is smaller than the width of Δha, between the minimum value of the slope signal SRAMP and a second maximum value of the slope signal SRAMP. In addition, the slope signal SRAMP is adjusted to include the second central value corresponding to pe, which is lower than the first central value pa, as a second minimum value, and the PWM signal SPWM has a pulse width of Δte which corresponds to a gap between t10 and t11 and is greater than the pulse width Δta. Accordingly, the duty of the PWM signal SPWM increases, thereby increasing the output voltage VOUT. In a third section in which the feed-back output voltage VOUT becomes equal to the reference voltage VREF, the converter returns to the normal state.

Referring to FIG. 13, in the first section in which the converter, in other words, the semiconductor device 100, operates in the normal state, the slope signal SRAMP includes the first amplitude corresponding to a width of Δha between the minimum value of the slope signal SRAMP and the first maximum value of the slope signal SRAMP. In addition, the slope signal SRAMP includes the first central value corresponding to pa as the first minimum value, and the PWM signal SPWM has a constant pulse width of Δta corresponding to a gap between t1 and t2.

However, in the second section in which the feed-back output voltage VOUT is higher than the reference voltage VREF since the converter operates in the abnormal state, the slope signal SRAMP includes the second amplitude corresponding to a width of Δhf, which is greater than the width of Δha, between the minimum value of the slope signal SRAMP and the second maximum value of the slope signal SRAMP. In addition, the slope signal SRAMP is adjusted to include the second central value corresponding to pf, which is higher than the first central value pa, as the second minimum value, and the PWM signal SPWM has a pulse width of Δtf which corresponds to a gap between t12 and t13 and is smaller than the pulse width of Δta. Accordingly, the duty of the PWM signal SPWM decreases, thereby decreasing the output voltage VOUT. In the third section in which the feed-back output voltage VOUT becomes equal to the reference voltage VREF, the converter returns to the normal state.

FIG. 14 is a circuit diagram of a slope signal controller 64 and a slope signal generator 54 according to an exemplary embodiment of the present inventive concept. A detailed description of elements similar to those shown in FIG. 8 will be omitted.

Referring to FIG. 14, the slope signal controller 64 according to the current embodiment includes a plurality of transistors, a resistor, and a bias current source Ibias. The slope signal generator 54 according to the current embodiment includes a plurality of transistors, a capacitor Cp, resistors, comparators, and an SR latch.

A third bias transistor Mb3 forms a current mirror circuit together with a fifth transistor M5. Here, the third bias transistor Mb3 may be, e.g., a p-type MOSFET. In this case, a gate terminal of the third bias transistor Mb3 is connected to a drain terminal of the fifth transistor M5. In addition, the input voltage VIN is applied to a source terminal of the third bias transistor Mb3.

A first (e.g., non-inversion) input terminal of a first comparator Comparator 1 is connected to a drain terminal of the third bias transistor Mb3, and a second (e.g., inversion) input terminal of the first comparator Comparator 1 is connected to a first terminal of the capacitor Cp. A first (e.g., non-inversion) input terminal of a second comparator Comparator 2 is connected to the first terminal of the capacitor Cp, and a second (e.g., inversion) input terminal of the second comparator Comparator 2 is connected to a first terminal of a second resistor Rb2. A first resistor Rb1 is connected between the first input terminal of the first comparator Comparator 1 and a second input terminal of the second comparator Comparator 2, and a second terminal of the second resistor Rb2 is connected to the ground.

When the slope signal controller 64 and the slope signal generator 54 are configured as shown in FIG. 14, the amplitude and central value of the slope signal SRAMP are changed as follows.

As described above for FIG. 8, as the control voltage increases or decreases, the current flowing into the capacitor Cp increases or decreases. The amplitude and central value of the slope signal SRAMP can be simultaneously changed by individually increasing or decreasing the maximum and minimum values of the slope signal SRAMP as well as a voltage that charges the capacitor Cp.

The first comparator Comparator 1 determines the maximum value of the slope signal SRAMP, and the second comparator Comparator 2 determines the minimum value of the slope signal SRAMP. Accordingly, an inter-terminal voltage of the second resistor Rb2 connected to the second input terminal of the second comparator Comparator 2 is used as the reference minimum value VMN of the slope signal SRAMP, and an inter-terminal voltage of the first resistor Rb1 connected between the first input terminal of the first comparator Comparator 1 and the second input terminal of the second comparator Comparator 2 corresponds to a difference between the maximum and minimum values of the slope signal SRAMP. Accordingly, when a current I3 flowing through the drain terminal of the third bias transistor Mb3 increases or decreases, the reference minimum value VMN of the slope signal SRAMP increases or decreases, and, at the same time, the difference between the maximum and minimum values of the slope signal SRAMP increases or decreases.

Therefore, when a current I1 flowing through the drain terminal of the fifth transistor M5 increases, a current I2 flowing through a drain terminal of a sixth transistor M6 increases, thereby increasing the voltage that charges the capacitor Cp. In addition, the current I3 flowing through the drain terminal of the third bias transistor Mb3 increases, and thus the inter-terminal voltage of the first resistor Rb1 and the inter-terminal voltage of the second resistor Rb2 increase. In this case, the inter-terminal voltage of the capacitor Cp is charged to the increased reference maximum value VMX (e.g., a value obtained by adding the inter-terminal voltage of the first resistor Rb1 to the inter-terminal voltage of the second resistor Rb2) of the slope signal SRAMP and then discharged to the increased reference minimum value VMN (e.g., the inter-terminal voltage of the second resistor Rb2) of the slope signal SRAMP. Accordingly, since the maximum and minimum values of the slope signal SRAMP increase individually, the amplitude and central value of the slope signal SRAMP increase.

Conversely, when the current I1 flowing through the drain terminal of the fifth transistor M5 decreases, the current I2 flowing through the drain terminal of the sixth transistor M6 decreases, thereby decreasing the voltage that charges the capacitor Cp. In addition, the current I3 flowing through the drain terminal of the third bias transistor Mb3 decreases, and thus the inter-terminal voltage of the first resistor Rb1 and the inter-terminal voltage of the second resistor Rb2 decrease. In this case, the inter-terminal voltage of the capacitor Cp is charged to the decreased reference maximum value VMX of the slope signal SRAMP and then discharged to the decreased reference minimum value VMN of the slope signal SRAMP. Accordingly, since the maximum and minimum values of the slope signal SRAMP decrease individually, the amplitude and central value of the slope signal SRAMP decrease.

If the reference maximum value VMX and the reference minimum value VMN of the slope signal SRAMP do not increase or decrease individually, the amplitude and central value of the slope signal SRAMP do not change even when the inter-terminal voltage of the capacitor Cp increases or decreases because the state of an eighth transistor M8 varies according to the outputs of the first and second comparators Comparator 1 and Comparator 2.

A power management device according to an exemplary embodiment of the present inventive concept includes one or more loads and a PWM control DC-DC converter. The PWM control DC-DC converter applies an output voltage VOUT appropriate for the operation of the loads to the loads based on a PWM signal SPWM.

As described above, the PWM control DC-DC converter includes the slope signal generator 50 which generates the slope signal SRAMP, the error signal generator 40 which generates the error signal SERR using the output voltage VOUT fed back thereto, the PWM signal generator 30 which generates the PWM signal SPWM using a difference between the slope signal SRAMP and the error signal SERR, and the slope signal controller 60 which adjusts a waveform of the slope signal SRAMP according to a difference between the output voltage VOUT and the reference voltage VREF.

In an exemplary embodiment of the present inventive concept, the slope signal SRAMP may be a ramp signal which has a predetermined slope and increases or decreases linearly. However, the slope signal SRAMP is not limited to the ramp signal. The slope signal SRAMP may also be a triangular wave signal or a sawtooth wave signal, for example. In addition, the output voltage VOUT input to the error signal generator 40 and the slope signal controller 60 may be a voltage fed back according to a predetermined voltage division ratio. Here, the voltage division ratio may have a value of 0 or 1, for example.

A semiconductor device according to an exemplary embodiment of the present inventive concept changes a duty of a PWM signal without time delay by changing at least one of an amplitude and a central value of a slope signal. Therefore, the semiconductor device can have fast transient response time characteristics for a change in an output voltage and a change in a reference voltage.

A power management device according to an exemplary embodiment of the present inventive concept changes a duty of a PWM signal without time delay by changing at least one of an amplitude and a central value of a slope signal. Therefore, the power management device can have fast transient response time characteristics for a change in an output voltage and a change in a reference voltage.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims.

What is claimed is:

1. A semiconductor device, comprising:
a slope signal generator configured to generate a slope signal;
an error signal generator configured to generate an error signal in response to an output voltage;
a pulse width modulation (PWM) signal generator configured to generate a PWM signal using a difference between the slope signal and the error signal; and
a slope signal controller configured to adjust the slope signal according to a difference between the output voltage and a reference voltage.

2. The semiconductor device of claim 1, wherein the slope, signal controller is configured to control the slope signal to have a first amplitude in a first section and a second amplitude different from the first amplitude in a second section different from the first section according to the difference between the output voltage and the reference voltage.

3. The semiconductor device of claim 2, wherein the slope signal generator comprises a first comparator and a second comparator which are different from each other, wherein the first comparator is configured to determine a maximum value of the slope signal, the second comparator is configured to determine a minimum value of the slope signal, and the slope signal controller is configured to control an increase or decrease in a difference between the maximum value and the minimum value of the slope signal.

4. The semiconductor device of claim 1, wherein the slope signal controller is configured to control the slope signal to have a first central value in a first section and a second central value different from the first central value in a second section different from the first section according to the difference between the output voltage and the reference voltage.

5. The semiconductor device of claim 4, wherein the slope signal generator comprises a first comparator and a second comparator which are different from each other, wherein the first comparator is configured to determine a maximum value of the slope signal, the second comparator is configured to determine a minimum value of the slope signal, and the slope signal controller is configured to control an equal increase or decrease of the maximum and minimum values of the slope signal.

6. The semiconductor device of claim 1, wherein the slope signal controller is configured to control the slope signal to have a first amplitude and a first central value in a first section and a second amplitude different from the first amplitude and a second central value different from the first central value in a second section different from the first section according to the difference between the output voltage and the reference voltage.

7. The semiconductor device of claim 6, wherein the slope signal generator comprises a first comparator and a second comparator which are different from each other, wherein the first comparator is configured to determine a maximum value of the slope signal, the second comparator is configured to determine a minimum value of the slope signal, and the slope signal controller is configured to control individual increases or decreases in the maximum and minimum values of the slope signal.

8. The semiconductor device of claim 1, wherein the output voltage is a voltage fed back to the error signal generator according to a predetermined voltage division ratio.

9. A semiconductor device, comprising:
an error signal generator configured to generate an error signal;
a slope signal generator configured to generate a slope signal which comprises a first amplitude in a first section and a second amplitude different from the first amplitude in a second section; and
a pulse width modulation (PWM) signal generator configured to generate a PWM signal using a difference between the slope signal and the error signal.

10. The semiconductor device of claim 9, further comprising a switch circuit configured to generate an output voltage based on the PWM signal and apply the output voltage to a load, wherein the error signal generator generates the error signal using the output voltage.

11. The semiconductor device of claim 10, wherein the error signal generator generates the error signal based on a result of a comparison between the output voltage and a reference voltage.

12. The semiconductor device of claim 9, wherein the first amplitude is a width between a minimum value and a first maximum value of the slope signal, the second amplitude is a width between the minimum value and a second maximum value of the slope signal, and the first maximum value and the second maximum value of the slope signal are different from each other.

13. The semiconductor device of claim 9, wherein a level of the error signal is higher than the minimum value of the slope signal.

14. The semiconductor device of claim 9, wherein the slope signal generator comprises a first comparator and a second comparator, wherein the first comparator is configured to determine a maximum value of the slope signal, and the second comparator is configured to determine a minimum value of the slope signal.

15. The semiconductor device of claim 14, wherein a difference between the maximum value and the minimum value of the slope signal in the first section is different from a difference between the maximum value and the minimum value of the slope signal in the second section.

16. A power management device, comprising:
an error amplifier configured to generate an error signal using an output voltage and a reference voltage;
a first signal generator configured to generate a first signal having a variable amplitude or central oscillation point based on the output voltage and the reference voltage; and
a pulse width modulation (PWM) signal generator configured to generate a PWM signal using the first signal and the error signal.

17. The power management device of claim 16, further comprising a first signal controller configured to control the variability of the amplitude or central oscillation point of the first signal according to a difference between the output voltage and the reference voltage.

18. The power management device of claim 16, wherein the output voltage is an output voltage of a switch circuit.

19. The power management device of claim 16, wherein the first signal is a ramp signal, triangular wave signal or sawtooth wave signal.

20. The power management device of claim 16, wherein a duty of the PWM signal is based on the error signal and first signal.
